(19) United States
(12) Patent Application Publication
(10) Pub. No.: US 2007/0065578 A1
(43) Pub. Date: Mar. 22, 2007

(54) Treatment processes for a batch ALD reactor

(75) Inventor: Brendan Anthony McDougall, Livermore, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/232,455

(22) Filed: Sep. 21, 2005

(51) Int. Cl. C23C 16/00

(52) U.S. Cl. 427/248.1

(57) ABSTRACT

Embodiments of the invention provide treatment processes to reduce substrate contamination during a fabrication process within a vapor deposition chamber. A treatment process may be conducted before, during or after a vapor deposition process, such as an atomic layer deposition (ALD) process. In one example of an ALD process, a process cycle, containing an intermediate treatment step and a predetermined number of ALD cycles, is repeated until the deposited material has a desired thickness. The chamber and substrates may be exposed to an inert gas, an oxidizing gas, a nitriding gas, a reducing gas or plasmas thereof during the treatment processes. In some examples, the treatment gas contains ozone, water, ammonia, nitrogen, argon or hydrogen. In one example, a process for depositing a hafnium oxide material within a batch process chamber includes a pretreatment step, an intermediate step during an ALD process and a post-treatment step.

### BACKGROUND OF THE INVENTION

1. Field of the Invention

Embodiments of the invention generally relate to fabrication processes, and more specifically, to treatment processes for hardware or substrates prior to, during or subsequent to substrate fabrication.

2. Description of the Related Art

Following other technologies, the microelectronics industry requires the deposition of materials with an atomic layer resolution. Atomic layer deposition (ALD) processes were developed about 30 years ago to fabricate electroluminescent flat panel displays. In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive. Feature sizes of less than 40 nm and aspect ratios of 30 are desired during fabrication processes for advanced technology nodes (0.65 μm and smaller). While conventional chemical vapor deposition (CVD) processes have proved successful for technology nodes larger than 0.65 μm, aggressive device geometries require film deposition with atomic layer resolution. Either the required film thickness is a few atomic layers thick or the device geometry (e.g., high aspect ratio trench) excludes material deposited by a CVD process. Therefore, the requirement for ALD processes is recognized during certain fabrication protocols.

Reactant gases are sequentially introduced into a process chamber containing a substrate or multiple substrates during an ALD process. Generally, a first reactant is administered into the process chamber and is adsorbed onto the substrate surface. A second reactant is administered into the process chamber and reacts with the first reactant to form a deposited material and reaction byproducts. Ideally, the two reactants are not simultaneously present within the process chamber. Therefore, a purge step is typically carried out to further remove gas between each delivery of a reactant gas. For a single substrate ALD process, the purge step may be a continuous purge with the carrier gas or a pulse purge between each delivery of a reactant gas.

Atomic layer deposition processes have been successfully implemented for depositing dielectric layers, barrier layers and conductive layers. Dielectric materials deposited by ALD processes for gate and capacitor applications include silicon nitride, silicon oxynitride, hafnium oxide, hafnium silicate, zirconium oxide and tantalum oxide. Generally, an ALD process provides a deposited material with lower impurities and better conformality and control of film thickness when compared to a CVD process. However, an ALD process usually has a slower deposition rate than a comparable CVD process for depositing a material of similar composition. Therefore, an ALD process that reduces the overall fabrication throughput may be less attractive than the comparable CVD process. By utilizing a batch tool, productivity may be improved without sacrificing the benefits provided by ALD processes.

A batch deposition process may be used to increase throughput during a fabrication process by simultaneously processing multiple substrates within a single chamber. However, batch processes using CVD techniques remain limited due to the smaller geometries of modern devices. Although an ALD process may provide a material with smaller geometries unobtainable by a CVD process, an increased time interval may be realized for hardware maintenances on an ALD equipped tool. Also, a batch deposition process utilizing ALD techniques may suffer slow initiation of the deposited material (e.g., seeding effect or incubation delay), deposited materials containing deleterious molecular fragments from the reactants and high levels of particulate contaminants on the substrates and throughout the chamber due to cross-contamination of the precursors or due to condensation of reaction byproducts. Deposited materials containing defects, impurities or contaminants provide dielectric films with large leakage current, metal films with large resistivity or barrier films with large permeability. Such film properties are inadequate and cause inevitable device failure. Also, the ALD equipped tool may need to be shut-down for maintenance due to cumulative contamination after multiple processes. Overall, the fabrication process suffers a reduction in product throughput and an increased cost.

Therefore, there is a need for a process to reduce incubation delay of a material deposited on a substrate within a process chamber, to reduce impurity or defect formation of the deposited material, and to reduce contaminants within the process chamber. Preferably, the process may be conducted on an ALD batch tool.

### SUMMARY OF THE INVENTION

In one embodiment of the invention, a method for forming a material on a substrate is provided which includes exposing at least one substrate within a process chamber to the pretreatment process, exposing the substrates to an ALD process for forming a material on the substrates and subsequently exposing the substrates and the process chamber to a post-treatment process. In one example, the ALD process includes exposing the substrates sequentially to at least two chemical precursors during an ALD cycle, repeating the ALD cycle for a predetermined number of cycles (i.e., an ALD loop) and conducting an intermediate treatment process between ALD loops.

The method may be conducted within a batch process chamber or a single wafer process chamber. In a preferred embodiment, the chamber is an ALD batch chamber containing a plurality of substrates, such as 25, 50, 100 substrates. The pretreatment process, the intermediate treatment processes and the post-treatment process may contain a treatment gas, such as an inert gas, an oxidizing gas, a nitriding gas, a reducing gas, plasmas thereof, derivatives thereof or combinations thereof. For example, a treatment gas may contain ozone, water, ammonia, nitrogen, argon, hydrogen, plasmas thereof, derivatives thereof or combinations thereof. In one example, the treatment gas contains an ozone/oxygen (O₃/O₂) mixture, such that the ozone is at a concentration within a range from about 1 atomic percent (at %) to about 50 at %, preferably, from about 5 at % to about 30 at %, and more preferably, from about 10 at % to about 20 at %. In another example, the treatment gas contains water vapor formed from an oxygen source and a hydrogen source produced by a catalytic water vapor generator. In another example, the treatment gas contains ammonia or an ammonia plasma.

In another embodiment, a method for forming a material on a substrate within a process chamber is provided which includes exposing a batch process chamber to a pretreatment process, exposing a plurality of substrates within the batch process chamber to an ALD process containing at least one treatment process and thereafter, exposing the process chamber to a post-treatment process. In one example, the treatment process is conducted after a predetermined number of ALD cycles, such that the treatment process and the predetermined number of ALD cycles are repeated during a process cycle. The process cycle may be repeated to form the deposited material such as hafnium oxide, hafnium silicate, aluminum oxide, silicon oxide, hafnium aluminate, derivatives thereof or combinations thereof.

In one example, a plurality of substrates within a batch process chamber is exposed to a pretreatment process and an ALD process to form a hafnium-containing material. The ALD process contains at least one intermediate treatment process subsequent to an ALD cycle that exposes the substrates sequentially to a hafnium precursor and an oxidizing gas. The ALD cycle may be repeated until the hafnium-containing layer has a predetermined thickness.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of the invention and are therefore not to be considered limiting of its scope, for the invention may admit to other equally effective embodiments.

FIG. 1 illustrates a process sequence according to an embodiment described herein; and

FIG. 2 illustrates a process sequence according to another embodiment described herein.

### DETAILED DESCRIPTION

Embodiments of the invention provide methods for preparing materials used in a variety of applications, especially for high-k dielectric materials and barrier materials used in transistor and capacitor fabrication. The methods provide treatment processes for a vapor deposition chamber and treatment and deposition processes for the substrates therein. In a preferred embodiment, an atomic layer deposition (ALD) process may be used to control elemental composition of the deposited materials. The ALD process may be conducted within a single substrate process chamber, but preferably, is conducted within a batch process chamber.

In one embodiment, the process chamber is exposed to a pretreatment process prior to a deposition process, such as an ALD process or a chemical vapor deposition (CVD) process. In one example, the process chamber is treated containing no substrates within, while in another example, the process chamber is treated containing at least one substrate, usually, a plurality of substrates (e.g., 25, 50, 100 or more). In another embodiment, the process chamber is exposed to an intermediate treatment process during the deposition process. In one example, the deposition process may be stopped, the intermediate treatment process conducted and the deposition process started again. In another example, a deposition process is stopped, the intermediate treatment process is conducted and an alternative deposition process is started. In another embodiment, a process chamber is exposed to a post-treatment process subsequent to the deposition process. In one example, the substrates are removed and the process chamber is treated empty, while in another example, the process chamber is treated containing a substrate or a plurality of substrates. The treatment process generally includes exposing the process chamber or the substrates to a treatment gas for a predetermined time at a predetermined temperature. The treatment gases usually contain a reactive compound, such as ammonia or ozone.

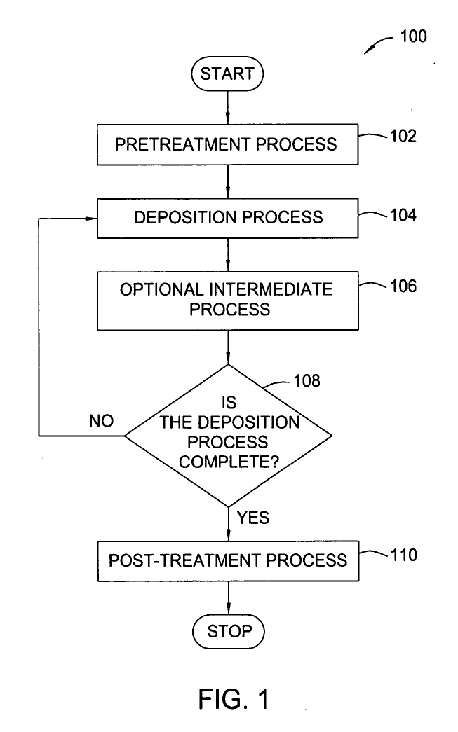

In FIG. 1, a flow chart depicts process 100 as described in one embodiment herein. Process 100 provides conducting a pretreatment process (step 102), a deposition process (step 104), an optional intermediate treatment process (step 106) and a post-treatment process (step 110) within a process chamber. Process 100 further provides an option for repeating the deposition process and the intermediate treatment process (step 108).

A pretreatment gas may be administered into the process chamber to further reduce contaminants prior to beginning a deposition process (step 102). The pretreatment gas is generally selected in consideration of the subsequent deposition process of step 104. The pretreatment gas may contain a reactive gas and a carrier gas and include nitrogen, argon, helium, hydrogen, oxygen, ozone, water, ammonia, silane, disilane, diborane, derivatives thereof, plasmas thereof or combinations thereof. In one example, a pretreatment gas may contain an oxidizing gas, such as ozone or water vapor prior to depositing an oxide material (e.g., hafnium oxide, aluminum oxide or silicon oxide), a silicate material (e.g., hafnium silicate or zirconium silicate) or an aluminate material (e.g., hafnium aluminate). In another example, a pretreatment gas may contain a nitriding gas, such as ammonia, nitrogen or nitrogen plasma prior to depositing a nitride material, such as silicon nitride or hafnium silicon oxynitride. In some examples, the pretreatment gas contains nitrogen, argon, helium, hydrogen, forming gas or combinations thereof.

The process chamber may be a batch process chamber or a single wafer for forming a material by a vapor deposition process, such as an ALD process or a conventional CVD process. Therefore, the process chamber may contain at least one substrate or a plurality of substrates. In one example, the process chamber is a mini-batch ALD process chamber capable of holding at least about 25 substrates. Larger batch ALD process chambers useful by embodiments described herein have a capacity of about 50 substrates, 100 substrates or more.

The substrates may be placed into the process chamber during any portion of step 102. In one example, the substrates are placed into the process chamber before beginning a pretreatment process. In another example, the substrates are placed into the process chamber after completing a pretreatment process. In another example, the substrates are placed into the process chamber during a pretreatment process, such that the process chamber is exposed to a pretreatment gas during a first time period before the substrates are placed into the process chamber and thereafter, both the process chamber and the substrates are exposed to the same or a different pretreatment gas during a second time period.

In one embodiment, the process chamber is a batch process chamber for vapor deposition processes, for example, a batch ALD chamber. The pretreatment gas may have a flow rate within a range from about 0.1 standard liters per minute (slm) to about 30 slm, preferably, from about 1 slm to about 20 slm, and more preferably, from about 5 slm to about 10 slm. The interior of the process chamber may be heated during the pretreatment process to a temperature within a range from about 100° C. to about 700° C., preferably, from about 150° C. to about 400° C., and more preferably, from about 200° C. to about 300° C. The process chamber may be maintained at a pressure within a range from about 1 mTorr to about 100 Torr, preferably, from about 10 mTorr to about 50 Torr, and more preferably, from about 5 mTorr to about 5 Torr. In one example, the process chamber may be maintained at a pressure of about 0.6 Torr during a process to form a nitride material or an oxide material. The temperature and pressure of the process chamber may be held constant or adjusted throughout step 102. In one example, the pretreatment process may begin about 12 hours before starting a deposition process. However, the pretreatment process may last for a time period within a range from about 5 minutes to about 6 hours, preferably from about 10 minutes to about 2 hours, and more preferably, from about 20 minutes to about 60 minutes.

During step 104, a deposition process is conducted within the process chamber to form a material on the substrates. The deposition process may be a vapor deposition process, such as an ALD process or a CVD process and may include a plasma-enhanced ALD (PE-ALD) process, a plasma-enhanced CVD (PE-CVD) process, a pulsed CVD process or combinations thereof. In one example, an ALD process sequentially exposes the substrates to a metal precursor and an oxidizing gas to form a metal oxide material. In another example, an ALD process sequentially exposes the substrates to a metal precursor, an oxidizing gas, a silicon precursor and the oxidizing gas to form a metal silicate material.

The material deposited during the deposition step may be a dielectric material, a barrier material, a conductive material, a nucleation/seed material or an adhesion material. In one embodiment, the deposited material may be a dielectric material containing oxygen and/or nitrogen and at least one additional element, such as hafnium, silicon, tantalum, titanium, aluminum, zirconium, lanthanum or combinations thereof. For example, the dielectric material may contain hafnium oxide, zirconium oxide, tantalum oxide, aluminum oxide, lanthanum oxide, titanium oxide, silicon oxide, silicon nitride, oxynitrides thereof (e.g., HfOₓN_{y}), silicates thereof (e.g., HfSiₓO_{y}), aluminates thereof (e.g., HfAlₓO_{y}), silicon oxynitrides thereof (e.g., HfSiₓO_{y}N_{z}), derivatives thereof or combinations thereof. In one example, the dielectric material may also contain multiple layers of varying compositions. For example, a laminate film may be formed by depositing a silicon oxide layer onto a hafnium oxide layer to form a hafnium silicate material. A third layer of aluminum oxide may be deposited on the hafnium silicate to further provide a hafnium aluminum silicate material.

In another example, a process for forming a dielectric material uses an oxidizing gas containing water vapor. The water vapor may be formed by flowing a hydrogen source gas and an oxygen source gas into a water vapor generator (WVG) system containing a catalyst. Pretreatment processes and deposition processes utilizing a WVG system that may be used herein are further described in commonly assigned and co-pending U.S. patent application Ser. No. 11/127,767, filed May 12, 2005, and entitled, “Apparatuses and Methods for Atomic Layer Deposition of Hafnium-containing High-K Materials,” which is incorporated herein by reference in its entirety.

The process chamber may be exposed to an optional intermediate treatment process during step 106 of process 100. The interior of the process chamber may be heated to a temperature within a range from about 100° C. to about 700° C., preferably, from about 150° C. to about 400° C., and more preferably, from about 200° C. to about 300° C. and maintained at a pressure within a range from about 1 mTorr to about 100 Torr, preferably, from about 10 mTorr to about 50 Torr, and more preferably, from about 5 Torr to about 10 Torr, such as about 8 Torr. The temperature and pressure of the process chamber may be held constant or adjusted throughout the intermediate treatment process. A treatment gas may be administered into the process chamber during an intermediate treatment process and may contain the same gas or a different gas as used as the pretreatment gas (step 102) or the reactant gas (step 104). Therefore, a treatment gas may contain nitrogen, argon, helium, hydrogen, oxygen, ozone, water, ammonia, silane, disilane, diborane, derivatives thereof, plasmas thereof or combinations thereof.

In one example during a batch process, a treatment gas may have a flow rate within a range from about 0.1 slm to about 30 slm, preferably, from about 1 slm to about 20 slm, and more preferably, from about 5 slm to about 10 slm. The intermediate treatment process may last for a time period within a range from about 5 minutes to about 6 hours, preferably from about 10 minutes to about 2 hours, and more preferably, from about 20 minutes to about 60 minutes.

The substrates are usually kept within the process chamber during step 106. However, the substrates may be removed from the process chamber during any portion of step 106. In one example, the substrates are removed from the process chamber before starting the intermediate treatment process. In another example, the substrates are removed from the process chamber after completing the intermediate treatment process. In another example, the substrates are removed from the process chamber during the intermediate treatment process, such that the process chamber and the substrates are exposed to a treatment gas during a first time period before the substrates are removed from the process chamber and thereafter, the process chamber is exposed to the same or a different treatment gas during a second time period.

In one embodiment, the deposition process is stopped, the chamber and the substrates are exposed to a treatment process and then the deposition process is started again (step 108). Therefore, the treatment process is intermediate with the deposition process. A cycle of steps 104, 106 and 108 form a deposition/treatment process that may be repeated as a plurality of cycles to form the deposited material. The intermediate treatment process reduces particles and other contaminants throughout the process chamber and on the substrates. In one example, an intermediate treatment process may occur after each ALD cycle during an ALD process. In another example, an intermediate treatment process may occur after a multitude of ALD cycles, such as after every 10 ALD cycles or every 20 ALD cycles. In other examples, an intermediate treatment process may occur during a CVD process, such that, the CVD process is stopped, the treatment process is conducted for a predetermined time and the CVD process is resumed to continue depositing material on the substrate.

In another embodiment, step 106 is omitted, so that no intermediate treatment process is conducted and deposition process is over at step 108. Generally, the deposition process is over once a predetermined thickness of the deposited material is formed during step 104.

The process chamber may be exposed to a post-treatment process during step 110 of process 100. The interior of the process chamber may be heated to a temperature within a range from about 100° C. to about 700° C., preferably, from about 150° C. to about 4004° C., and more preferably, from about 200° C. to about 300° C. and maintained at a pressure within a range from about 1 mTorr to about 100 Torr, preferably, from about 10 mTorr to about 50 Torr, and more preferably, from about 5 Torr to about 10 Torr, such as about 8 Torr. The temperature and pressure of the process chamber may be held constant or adjusted throughout step 110. A post-treatment gas may be administered into the process chamber during the post-treatment gas and may contain the same gas or a different gas as used as the pretreatment gas (step 102), the reactant gas (step 104) or the treatment gas (step 106). Therefore, a post-treatment gas may contain nitrogen, argon, helium, hydrogen, oxygen, ozone, water, ammonia, silane, disilane, diborane, derivatives thereof, plasmas thereof or combinations thereof and may have a flow rate within a range from about 0.1 slm to about 30 slm, preferably, from about 1 slm to about 20 slm, and more preferably, from about 5 slm to about 10 slm. The post-treatment process may last for a time period within a range from about 5 minutes to about 6 hours, preferably from about 10 minutes to about 2 hours, and more preferably, from about 20 minutes to about 60 minutes.

The substrates may be removed from the process chamber during any portion of step 110. In one example, the substrates are removed from the process chamber before starting the post-treatment process. In another example, the substrates are removed from the process chamber after completing the post-treatment process. In another example, the substrates are removed from the process chamber during the post-treatment process, such that the process chamber and the substrates are exposed to a post-treatment gas during a first time period before the substrates are removed from the process chamber and thereafter, the process chamber is exposed to the same or a different post-treatment gas during a second time period.

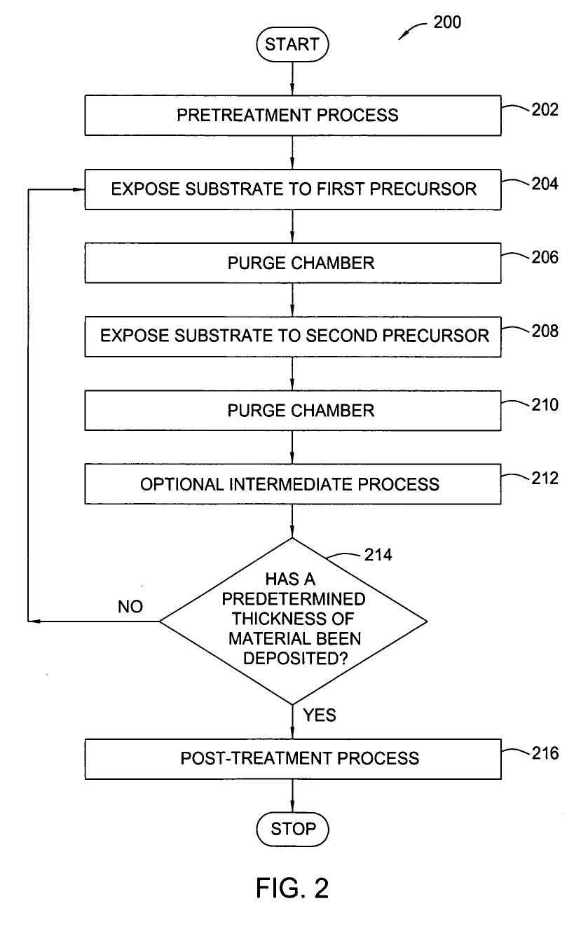

In another embodiment, FIG. 2 illustrates process 200 for forming a deposited material, such as hafnium oxide, onto a substrate by an ALD process. Process 200 may contain a pretreatment process (step 202), an ALD cycle (steps 204-214) and a post-treatment process (step 216). In one example, process 200 is configured for a batch ALD process containing an ALD cycle to expose the substrates with a first precursor (e.g., hafnium precursor) introduced into the process chamber alone or in combination with a carrier gas for a time period within a range from about 1 second to about 90 seconds (step 204). Next, a purge gas is introduced into the process chamber for a time period within a range from about 1 second to about 60 seconds (step 206) to purge or otherwise remove any residual precursor or by-products. Subsequently, the substrate is exposed to a second precursor (e.g., O₃ or H₂O) introduced into the process chamber alone or in combination with a carrier gas for a time period within a range from about 1 seconds to about 90 second (step 208). Thereafter, the purge gas is again administered into the process chamber for a time period within a range from about 1 second to about 60 seconds (step 210).

In one embodiment, the ALD cycle may contain an evacuation step after each of steps 204, 206, 208 and 210. The process chamber is at least partially evacuated during the evacuation step, if not substantially or completely evacuated. The evacuation step may last for a time period within a range from about 1 second to about 5 minutes, preferably, from about 5 seconds to about 2 minutes, and more preferably, from about 10 seconds to about 60 seconds. The process chamber may be evacuated to a pressure within a range from about 50 mTorr to about 5 Torr, such as about 100 mTorr.

An optional intermediate treatment process (step 212) may be performed to further remove any remaining precursor gases, by-products, particulates or other contaminants within the process chamber. The intermediate treatment process may be conducted after any of steps 204, 206, 208 or 210 or after any cycle of steps 204, 206, 208 and 210. Usually, the intermediate treatment process is performed at a predetermined temperature for a time period within a range from about 1 minute to about 20 minutes, preferably, from about 2 minutes to about 15 minutes, and more preferably, from about 3 minutes to about 10 minutes, such as about 5 minutes. In one example, the intermediate treatment process contains a rather chemically inert treatment gas, such as nitrogen or argon. In another example, the treatment gas contains an oxidizing gas that may include ozone, oxygen, water, hydrogen peroxide, plasma thereof or combinations thereof. In another example, the treatment gas contains a reducing gas that may include hydrogen, diborane, silane, plasmas thereof or combinations thereof.

Each ALD cycle (steps 204 through 212) forms a layer of material (e.g., hafnium oxide) on the substrates. Usually, each deposition cycle forms a layer having a thickness within a range from about 0.1 Å to about 10 Å. Depending on specific device requirements, subsequent deposition cycles may be needed to deposit the material having a desired thickness (step 214). As such, a deposition cycle (steps 204 through 214) may be repeated to achieve the predetermined thickness of the material.

The process chamber may be exposed to a pretreatment process during step 202, as described herein for step 102. In one example, the process chamber is exposed to a pretreatment process prior to loading the substrates into the process chamber. In another example, the process chamber contains at least one substrate, preferably a plurality of substrates during the pretreatment process. Multiple pretreatment processes may be conducted within the process chamber during step 202. Therefore, the process chamber and the substrates may each be exposed to different pretreatment processes. In one example, an empty process chamber may be exposed to a pretreatment process for numerous hours (e.g., about 6-12 hours) before loading the substrates. Thereafter, the substrates are loaded into the process chamber and exposed to a pretreatment process, such as a pre-soak step prior to a deposition process.

The substrates may be terminated with a variety of functional groups after being exposed to a pretreatment process or a pre-soak step. The pre-soak step may be a portion of the overall pretreatment process. Functional groups that may be formed include hydroxyls (OH), alkoxy (OR, where R=Me, Et, Pr or Bu), oxygen radicals and aminos (NR or NR₂, where R=H, Me, Et, Pr or Bu). The pretreatment gas may include oxygen (O₂), ozone (O₃), atomic-oxygen (O), water (H₂O), hydrogen peroxide (H₂O₂), nitrous oxide (N₂O), nitric oxide (NO), dinitrogen pentoxide (N₂O₅), nitrogen dioxide (NO₂), ammonia (NH₃), diborane (B₂H₆), silane (SiH₄), disilane (Si₂H₆), hexachlorodisilane (Si₂Cl₆), hydrogen (H₂), atomic-H, atomic-N, alcohols, amines, derivatives thereof or combination thereof. The functional groups may provide a base for an incoming chemical precursor to attach on the substrate surface. During a pretreatment process, a substrate surface may be exposed to a reagent for a time period within a range from about 1 second to about 2 minutes, preferably from about 5 seconds to about 60 seconds. Additional pretreatment processes, pre-soak steps and deposition processes that may be used herein are further described in commonly assigned U.S. Pat. No. 6,858,547, and in commonly assigned and co-pending U.S. Ser. No. 10/302,752, filed Nov. 21, 2002, entitled, “Surface Pre-Treatment for Enhancement of Nucleation of High Dielectric Constant Materials,” and published US 20030232501, which are incorporated herein by reference in their entirety.

In one example of a pre-soak step, the substrates are exposed to an oxidizing gas containing water vapor generated from the water vapor generator (WVG) system. The pre-soak process provides the substrate surface with hydroxyl terminated functional groups that react with precursors containing amino-type ligands (e.g., TDEAH, TDMAH, TDMAS or Tris-DMAS) during a subsequent exposure (e.g., step 204). Pretreatment processes, pre-soak steps and deposition processes that utilize a WVG system and may be used herein are further described in commonly assigned and co-pending U.S. Ser. No. 11/127,767, filed May 12, 2005, and entitled, “Apparatuses and Methods for Atomic Layer Deposition of Hafnium-containing High-K Materials,” which is incorporated herein by reference in its entirety.

Although process 200 may be used to form a variety of materials, further examples of process 200 provide ALD processes to form a hafnium oxide material. In one example, the ALD process may be conducted in a mini-batch process chamber maintained at a pressure within a range from about 1 mTorr to about 100 Torr, preferably, from about 10 mTorr to about 50 Torr, and more preferably, from about 5 Torr to about 10 Torr, such as about 8 Torr. The chamber is usually heated to a temperature within a range from about 70° C. to about 800° C., preferably, from about 100° C. to about 500° C., and more preferably, from about 150° C. to about 350° C.

A first precursor (e.g., hafnium precursor) may be introduced into the process chamber at a rate within a range from about 100 standard cubic centimeters per minute (sccm) to about 5 slm, preferably, from about 500 sccm to about 4 slm, and more preferably, from about 1 slm to about 3 slm (step 204). The first precursor may be introduced into the process chamber with a carrier gas (e.g., nitrogen or argon) for a time period within a range from about 1 second to about 5 minutes, preferably, from about 5 seconds to about 2 minutes, and more preferably, from about 10 seconds to about 90 seconds. In one example, the first precursor is a hafnium precursor, such as a hafnium halide (e.g., HfCl₄) or a hafnium amino compound. Hafnium amino compounds are preferably tetrakis(dialkylamino)hafnium compounds that include tetrakis(diethylamino)hafnium ((Et₂N)₄Hf or TDEAH), tetrakis(dimethylamino)hafnium ((Me₂N)₄Hf or TDMAH) or tetrakis(ethylmethylamino)hafnium ((EtMeN)₄Hf or TEMAH).

A second precursor (e.g., an oxidizing gas) may be introduced into the process chamber at a rate within a range from about 100 sccm to about 5 slm, preferably, from about 500 sccm to about 4 slm, and more preferably, from about 1 slm to about 3 slm (step 208). The second precursor may be introduced into the process chamber with a carrier gas for a time period within a range from about 1 second to about 5 minutes, preferably, from about 5 seconds to about 2 minutes, and more preferably, from about 10 seconds to about 90 seconds. In one example, the second precursor is an oxidizing gas, such as oxygen, ozone, atomic-oxygen, water, hydrogen peroxide, nitrous oxide, nitric oxide, dinitrogen pentoxide, nitrogen dioxide, derivatives thereof or combinations thereof. In a preferred example, an oxidizing gas contains an ozone/oxygen (O₃/O₂) mixture, such that the ozone is at a concentration within a range form about 1 atomic percent (at %) to about 50 at %, preferably, from about 5 at % to about 30 at %, and more preferably, from about 10 at % to about 20 at %.

A purge gas (e.g., argon or nitrogen) is typically introduced into the process chamber at a rate within a range from about 100 sccm to about 5 slm, preferably, from about 500 sccm to about 4 slm, and more preferably, from about 1 slm to about 3 slm (steps 206 and 210). The purge gas may be introduced for a time period within a range from about 1 second to about 5 minutes, preferably, from about 5 seconds to about 2 minutes, and more preferably, from about 1 second to about 90 seconds. Suitable carrier gases or purge gases may include argon, nitrogen, helium, hydrogen, forming gas or combinations thereof.

In one embodiment, hydrogen gas or a forming gas may be used as a carrier gas, purge and/or a reactant gas to reduce halogen contamination from the deposited materials. Precursors that contain halogen atoms (e.g., HfCl₄, SiCl₄ or Si₂Cl₆) readily contaminate the deposited materials. Hydrogen is a reductant and produces hydrogen halides (e.g., HCl) as a volatile and removable by-product. Therefore, hydrogen may be used as a carrier gas or a reactant gas when combined with a precursor compound (e.g., hafnium, silicon, oxygen precursors) and may include another carrier gas (e.g., Ar or N₂).

Exemplary hafnium precursors useful for depositing materials containing hafnium may contain ligands such as halides, alkylaminos, cyclopentadienyls, alkyls, alkoxides, derivatives thereof or combinations thereof. Hafnium halide compounds useful as hafnium precursors may include HfCl₄, Hfl₄, and HfBr₄. Hafnium alkylamino compounds useful as hafnium precursors include (RR′N)₄Hf, where R or R′ are independently hydrogen, methyl, ethyl, propyl or butyl. Hafnium precursors useful for depositing hafnium-containing materials as described herein include (Et₂N)₄Hf, (EtMe)₄Hf, (MeEtN)₄Hf, (^{t}BuC₅H₄)₂HfCl₂, (C₅H₅)₂HfCl₂, (EtC₅H₄)₂HfCl₂, (Me₅C₅)₂HfCl₂, (Me₅C₅)HfCl₃, (ⁱPrC₅H₄)₂HfCl₂, (ⁱPrC₅H₄)HfCl₃, (^{t}BuC₅H₄)₂HfMe₂, (acac)₄Hf, (hfac)₄Hf, (tfac)₄Hf, (thd)₄Hf, (NO₃)₄Hf, (^{t}BuO)₄Hf, (ⁱPrO)₄Hf, (EtO)₄Hf, (MeO)₄Hf or derivatives thereof. Preferably, hafnium precursors used during the deposition process herein include HfCl₄, (Et₂N)₄Hf, (Me₂N)₄Hf and (EtMeN)₄Hf.

Exemplary silicon precursors useful for depositing silicon-containing materials (e.g., silicates) include silanes, alkylaminosilanes, silanols or alkoxy silanes. Silicon precursors may include (Me₂N)₄Si, (Me₂N)₃SiH, (Me₂N)₂SiH₂, (Me₂N)SiH₃, (Et₂N)₄Si, (Et₂N)₃SiH, (MeEtN)₄Si, (MeEtN)₃SiH, Si(NCO)₄, MeSi(NCO)₃, SiH₄, Si₂H₆, SiCl₄, Si₂Cl₆, MeSiCl₃, HSiCl₃, Me₂SiCl₂, H₂SiCl₂, MeSi(OH)₃, Me₂Si(OH)₂, (MeO)₄Si, (EtO)₄Si or derivatives thereof. Other alkylaminosilane compounds useful as silicon precursors include (RR′N)₄₋ₙSiHₙ, where R or R′ are independently hydrogen, methyl, ethyl, propyl or butyl and n=0-3. Other alkoxy silanes may be described by the generic chemical formula (RO)₄₋ₙSiLₙ, where R=methyl, ethyl, propyl or butyl and L=H, OH, F, Cl, Br or I and mixtures thereof. Preferably, silicon precursors used during deposition processes herein include (Me₂N)₃SiH, (Et₂N)₃SiH, (Me₂N)₄Si, (Et₂N)₄Si or SiH₄. Exemplary nitrogen precursors may include ammonia (NH₃), nitrogen (N₂), hydrazines (e.g., N₂H₄ or MeN₂H₃), amines (e.g., Me₃N, Me₂NH or MeNH₂), anilines (e.g., C₆H₅NH₂), organic azides (e.g., MeN₃ or Me₃SiN₃), inorganic azides (e.g., NaN₃ or Cp₂CoN₃), radical nitrogen compounds (e.g., N₃, N₂, N, NH or NH₂), derivatives thereof or combinations thereof. Radical nitrogen compounds may be produced by heat, hot-wires or plasma.

The ALD cycle is repeated during process 200 to form the deposited material with a predetermined thickness. The deposited material formed during the ALD process may have a thickness within a range from about 5 Å to about 300 Å, preferably from about 10 Å to about 200 Å, and more preferably from about 20 Å to about 100 Å. In some examples, hafnium oxide may be deposited having a thickness within a range from about 10 Å to about 60 Å, preferably from about 30 Å to about 40 Å. Generally, a hafnium oxide material is formed with an empirical chemical formula HfOₓ, where x is 2 or less. Hafnium oxide may have the molecular chemical formula HfO₂, but by varying process conditions (e.g., timing, temperature or precursors), hafnium oxides may be formed with less oxidized hafnium, for example, HfO_{1.8}.

The process chamber may be exposed to a post-treatment process during step 216, as described herein for step 110. In one example, the substrates are removed from the process chamber before starting the post-treatment process. In another example, the substrates are removed from the process chamber after completing the post-treatment process. In another example, the substrates are removed from the process chamber during the post-treatment process, such that the process chamber and the substrates are exposed to a post-treatment gas during a first time period before the substrates are removed from the process chamber and thereafter, the process chamber is exposed to the same or a different post-treatment gas during a second time period.

Batch process chambers for conducting vapor deposition processes, such as atomic layer deposition (ALD) or conventional chemical vapor deposition (CVD), that may be used during embodiments described herein are available from Applied Materials, Inc., located in Santa Clara, Calif., and are further disclosed in commonly assigned U.S. Pat. Nos. 6,352,593 and 6,321,680, in commonly assigned and co-pending U.S. Ser. No. 10/342,151, filed Jan. 13, 2003, entitled, “Method and Apparatus for Layer by Layer Deposition of Thin Films,” and published, US 20030134038, and in commonly assigned and co-pending U.S. Ser. No. 10/216,079, filed Aug. 9, 2002, entitled, “High Rate Deposition at Low Pressure in a Small Batch Reactor,” and published, US 20030049372, which are incorporated herein by reference in their entirety for the purpose of describing apparatuses used during deposition processes. Single wafer ALD chambers that may be used by embodiments described herein are further disclosed in commonly assigned U.S. Pat. No. 6,916,398, and in commonly assigned and co-pending U.S. patent application Ser. No. 11/127,753, filed May 12, 2005, and entitled, “Apparatuses and Methods for Atomic Layer Deposition of Hafnium-containing High-K Materials,” which are both incorporated herein by reference in their entirety.

A “substrate surface,” as used herein, refers to any substrate or material surface formed on a substrate upon which film processing is performed. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride. Substrates may have various dimensions, such as 200 mm or 300 mm diameter wafers, as well as, rectangular or square panes. Unless otherwise noted, embodiments and examples described herein are preferably conducted on substrates with a 200 mm diameter or a 300 mm diameter, more preferably, a 300 mm diameter. Processes of the embodiments described herein may deposit hafnium-containing materials on many substrates and surfaces. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers and patterned or non-patterned wafers. Substrates may be exposed to a post-treatment process to polish, etch, reduce, oxidize, hydroxylate, anneal and/or bake the substrate surface.

“Atomic layer deposition” or “cyclical deposition” as used herein refers to the sequential introduction of two or more reactive compounds to deposit a layer of material on a substrate surface. The two, three or more reactive compounds may alternatively be introduced into a reaction zone of a process chamber. Usually, each reactive compound is separated by a time delay to allow each compound to adhere and/or react on the substrate surface. In one aspect, a first precursor or compound A is pulsed into the reaction zone followed by a first time delay. Next, a second precursor or compound B is pulsed into the reaction zone followed by a second delay. During each time delay a purge gas, such as nitrogen, is introduced into the process chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, pulsing compound B and purge gas is a cycle. A cycle can start with either compound A or compound B and continue the respective order of the cycle until achieving a film with the desired thickness. In another embodiment, a first precursor containing compound A, a second precursor containing compound B and a third precursor containing compound C are each separately pulsed into the process chamber. Alternatively, a pulse of a first precursor may overlap in time with a pulse of a second precursor while a pulse of a third precursor does not overlap in time with either pulse of the first and second precursors. Alternatively, any of the aforementioned steps or permutations used herein during an ALD process may be separated or contain a pumping step.

A “pulse” as used herein is intended to refer to a quantity of a particular compound that is intermittently or non-continuously introduced into a reaction zone of a processing chamber. The quantity of a particular compound within each pulse may vary over time, depending on the duration of the pulse. The duration of each pulse is variable depending upon a number of factors such as, for example, the volume capacity of the process chamber employed, the vacuum system coupled thereto, and the volatility/reactivity of the particular compound itself. A “half-reaction” as used herein is intended to refer to a pulse of precursor step followed by a purge step or to a pulse of purge gas followed by a purge step.

### EXAMPLES

Examples 1-9 may be conducted within an ALD batch process chamber available from Applied Materials, Inc., located in Santa Clara, Calif., and mini-batch process chambers, as described in commonly assigned U.S. Pat. Nos. 6,352,593 and 6,321,680, in commonly assigned and co-pending U.S. Ser. No. 10/342,151, filed Jan. 13, 2003, entitled, “Method and Apparatus for Layer by Layer Deposition of Thin Films,” and published, US 20030134038, and in commonly assigned and co-pending U.S. Ser. No. 10/216,079, filed Aug. 9, 2002, entitled, “High Rate Deposition at Low Pressure in a Small Batch Reactor,” and published, US 20030049372, which are incorporated herein by reference in their entirety for the purpose of describing apparatuses to conduct the deposition processes.

### Example 1

### HfO₂ Deposition with O₃

A batch of 26 substrates is positioned on the susceptors of a boat within the mini-batch ALD chamber. The reactor is cycle purged between 0.6 Torr and vacuum with a nitrogen flow of about 5 slm. Subsequently, the process chamber is maintained at a pressure of about 0.6 Torr at about 250° C. and for a continuous flow of nitrogen for about 40 minutes and pretreated with 15 at % O₃ in oxygen for about 30-60 seconds. Thereafter, a hafnium oxide layer is formed during an ALD process by sequentially exposing the substrates to a hafnium precursor (TDMAH in nitrogen carrier gas) and ozone. The substrates are heated to about 250° C. and exposed to a plurality of ALD cycles. Each ALD cycle includes flowing TDMAH into the chamber for about 30 seconds, evacuating the chamber for about 10 seconds, flowing nitrogen (purge gas) into the chamber for about 15 seconds, evacuating the chamber for about 15 seconds, flowing ozone into the chamber for about 30-60 seconds, evacuating the chamber for about 10 seconds, flowing nitrogen into the chamber for about 10 seconds and evacuating the chamber for about 10 seconds. The ALD cycle is repeated a total of 17 times to form a hafnium oxide layer with a thickness of about 27 Å. Thereafter, the process chamber is maintained with a pressure of about 0.6 Torr at about 250° C. and exposed to a treatment gas containing nitrogen and ozone for about 5 minutes during an intermediate treatment process. Subsequently, 17 cycles of the ALD cycle and the intermediate treatment process are sequentially repeated as a deposition/treatment cycle. The deposition/treatment cycle is conducted 3 times to form a hafnium oxide layer with a thickness of about 80 Å. During a post-treatment process, the chamber is cycled purged with a post-treatment gas containing ozone at a pressure of 0.6 Torr or less at about 250° C. for about 20 cycles and continuously purging with a flow of nitrogen at about 0.5 slm and 0.6 Torr.

### Example 2

### HfO₂ Deposition with H₂O

A batch of 26 substrates is positioned on the susceptors of a boat within the mini-batch ALD chamber. The process chamber is maintained at a pressure of about 6 Torr at about 200° C. and exposed to a pretreatment gas containing ozone (15 at % ozone in oxygen) for about 40 minutes during a pretreatment process. Thereafter, a hafnium oxide layer is formed during an ALD process by sequentially exposing the substrates to a hafnium precursor (TDEAH in nitrogen carrier gas) and water vapor (in nitrogen carrier gas). The substrates are heated to about 200° C. and exposed to a plurality of ALD cycles. Each ALD cycle includes flowing TDEAH into the chamber for about 60 seconds, evacuating the chamber for about 30 seconds, flowing nitrogen (purge gas) into the chamber for about 30 seconds, evacuating the chamber for about 30 seconds, flowing water into the chamber for about 60 seconds, evacuating the chamber for about 30 seconds, flowing nitrogen into the chamber for about 30 seconds and evacuating the chamber for about 30 seconds. The ALD cycle is repeated a total of 10 times to form a hafnium oxide layer with a thickness of about 12 Å. Thereafter, the process chamber is maintained with a pressure of about 6 Torr at about 200° C. and exposed to a treatment gas containing nitrogen for about 5 minutes during an intermediate treatment process. Subsequently, 10 cycles of the ALD cycle and the intermediate treatment process are sequentially repeated as a deposition/treatment cycle. The deposition/treatment cycle is conducted 10 times to form a hafnium oxide layer with a thickness of about 120 Å. During a post-treatment process, the chamber is maintained with a pressure of about 6 Torr at about 200° C. for about 40 minutes and exposed to a post-treatment gas containing ozone.

### Example 3

### HfO₂ Homogenous Nanolaminate

A batch of 26 substrates is positioned on the susceptors of a boat within the mini-batch ALD chamber. The reactor is cycle purged between 0.6 Torr and vacuum with a nitrogen flow of about 5 slm. Subsequently, the process chamber is maintained at a pressure of about 0.6 Torr at about 250° C. and for a continuous flow of nitrogen for about 40 minutes and pretreated with 15 at % O₃ in oxygen for about 30-60 seconds. Thereafter, a hafnium oxide layer is formed during an ALD process by sequentially exposing the substrates to a hafnium precursor (TDEAH in nitrogen carrier gas) and ozone, as well as the hafnium precursor and water vapor. The substrates are maintained at to about 250° C. and exposed to a plurality of ALD cycles.

A first ALD cycle includes flowing TDEAH into the chamber for about 60 seconds, evacuating the chamber for about 30 seconds, flowing nitrogen (purge gas) into the chamber for about 30 seconds, evacuating the chamber for about 30 seconds, flowing ozone into the chamber for about 60 seconds, evacuating the chamber for about 30 seconds, flowing nitrogen into the chamber for about 30 seconds and evacuating the chamber for about 30 seconds. The ALD cycle is repeated a total of 5 times to form a hafnium oxide layer with a thickness of about 10 Å. Thereafter, the process chamber is maintained with a pressure of about 8 Torr at about 300° C. and exposed to a first treatment gas containing nitrogen and 15 at % ozone for about 5 minutes during a first intermediate treatment process, such that the ALD cycle and the first intermediate treatment process may be repeated as a first deposition/treatment cycle.

A second ALD cycle includes flowing TDEAH into the chamber for about 60 seconds, evacuating the chamber for about 30 seconds, flowing nitrogen (purge gas) into the chamber for about 30 seconds, evacuating the chamber for about 30 seconds, flowing water vapor into the chamber for about 60 seconds, evacuating the chamber for about 30 seconds, flowing nitrogen into the chamber for about 30 seconds and evacuating the chamber for about 30 seconds. The ALD cycle is repeated a total of 5 times to form a hafnium oxide layer with a thickness of about 10 Å. Thereafter, the process chamber is maintained with a pressure of about 8 Torr at about 300° C. and exposed to a second treatment gas containing nitrogen for about 5 minutes during a second intermediate treatment process, such that the ALD cycle and the second intermediate treatment process may be repeated as a second deposition/treatment cycle.

A cycle containing the first deposition/treatment cycle followed by the second deposition/treatment cycle is conducted 6 times to form a hafnium oxide layer with a thickness of about 120 Å. During a post-treatment process, the chamber is maintained with a pressure of about 8 Torr at about 250° C. for about 40 minutes and exposed to a post-treatment gas containing ozone.

### Example 4

### SiO₂ Deposition with O₃

A batch of 26 substrates is positioned on the susceptors of a boat within the mini-batch ALD chamber. The reactor is cycle purged between 8 Torr and vacuum with a nitrogen flow of about 5 slm. Subsequently, the process chamber is maintained at a pressure of about 8 Torr at about 300° C. and for a continuous flow of nitrogen for about 40 minutes and pretreated with 15 at % O₃ for about 30-60 seconds. Thereafter, a silicon oxide layer is formed during an ALD process by sequentially exposing the substrates to a silicon precursor (Tris-DMAS in nitrogen carrier gas) and ozone (15 at % ozone in oxygen). The substrates are heated to about 300° C. and exposed to a plurality of ALD cycles. Each ALD cycle includes flowing Tris-DMAS into the chamber for about 45 seconds, evacuating the chamber for about 20 seconds, flowing nitrogen (purge gas) into the chamber for about 20 seconds, evacuating the chamber for about 20 seconds, flowing ozone into the chamber for about 45 seconds, evacuating the chamber for about 20 seconds, flowing nitrogen into the chamber for about 20 seconds and evacuating the chamber for about 20 seconds. The ALD cycle is repeated a total of 20 times to form a silicon oxide layer with a thickness of about 25 Å. Thereafter, the process chamber is maintained with a pressure of about 8 Torr at about 300° C. and

exposed to a treatment gas containing nitrogen for about 6 minutes during an intermediate treatment process. Subsequently, 20 cycles of the ALD cycle and the intermediate treatment process are sequentially repeated as a deposition/treatment cycle. The deposition/treatment cycle is conducted 8 times to form a silicon oxide layer with a thickness of about 200 Å. During a post-treatment process, the chamber is maintained with a pressure of about 8 Torr at about 300° C. for about 30 minutes and exposed to a post-treatment gas containing ozone.

### Example 5

### Al₂O₃ Deposition with O₃

A batch of 26 substrates is positioned on the susceptors of a boat within the mini-batch ALD chamber. The process chamber is maintained at a pressure of about 5 Torr at about 280° C. and exposed to a pretreatment gas containing ozone (10 at % ozone in oxygen) for about 30 minutes during a pretreatment process. Thereafter, an aluminum oxide layer is formed during an ALD process by sequentially exposing the substrates to an aluminum precursor (trimethyl aluminum—TMA) and ozone (10 at % ozone in oxygen). The substrates were maintained at about 280° C. and exposed to a plurality of ALD cycles. Each ALD cycle includes flowing TMA into the chamber for about 5 seconds, evacuating the chamber for about 8 seconds, flowing nitrogen (purge gas) into the chamber for about 6 seconds, evacuating the chamber for about 10 seconds, flowing ozone into the chamber for about 15 seconds, evacuating the chamber for about 20 seconds, flowing nitrogen into the chamber for about 20 seconds and evacuating the chamber for about 20 seconds. The ALD cycle is repeated a total of 15 times to form an aluminum oxide layer with a thickness of about 20 Å. Thereafter, the process chamber is maintained with a pressure of about 5 Torr at about 300° C. and exposed to a treatment gas containing nitrogen for about 4 minutes during an intermediate treatment process. Subsequently, 15 cycles of the ALD cycle and the intermediate treatment process are sequentially repeated as a deposition/treatment cycle. The deposition/treatment cycle is conducted 6 times to form an aluminum oxide layer with a thickness of about 120 Å. During a post-treatment process, the chamber is maintained with a pressure of about 5 Torr at about 300° C. for about 30 minutes and exposed to a post-treatment gas containing ozone.

### Example 6

### HfSiO₄ Deposition with O₃

A batch of 26 substrates is positioned on the susceptors of a boat within the mini-batch ALD chamber. The process chamber is maintained at a pressure of about 8 Torr at about 250° C. and exposed to a pretreatment gas containing ozone (15 at % ozone in oxygen) for about 40 minutes during a pretreatment process. Thereafter, a hafnium silicate layer is formed during an ALD process by sequentially exposing the substrates to a hafnium precursor (TDEAH in nitrogen carrier gas), ozone (15 at % ozone in oxygen), a silicon precursor (Tris-DMAS in nitrogen carrier gas) and ozone. The substrates are heated to about 300° C. and exposed to a plurality of ALD cycles. Each ALD cycle includes flowing TDEAH into the chamber for about 60 seconds, evacuating the chamber for about 30 seconds, flowing nitrogen (purge gas) into the chamber for about 30 seconds, evacuating the chamber for about 30 seconds, flowing ozone into the chamber for about 60 seconds, evacuating the chamber for about 30 seconds, flowing nitrogen into the chamber for about 30 seconds and evacuating the chamber for about 30 seconds, flowing Tris-DMAS into the chamber for about 60 seconds, evacuating the chamber for about 30 seconds, flowing nitrogen into the chamber for about 30 seconds, evacuating the chamber for about 30 seconds, flowing ozone into the chamber for about 60 seconds, evacuating the chamber for about 30 seconds, flowing nitrogen into the chamber for about 30 seconds and evacuating the chamber for about 30 seconds. The ALD cycle is repeated a total of 5 times to form a hafnium silicate layer with a thickness of about 20 Å. Thereafter, the process chamber is maintained with a pressure of about 8 Torr at about 300° C. and exposed to a treatment gas containing nitrogen for about 5 minutes during an intermediate treatment process. Subsequently, 5 cycles of the ALD cycle and the intermediate treatment process are sequentially repeated as a deposition/treatment cycle. The deposition/treatment cycle is conducted 6 times to form a hafnium silicate layer with a thickness of about 120 Å. During a post-treatment process, the chamber is maintained with a pressure of about 8 Torr at about 250° C. for about 40 minutes and exposed to a post-treatment gas containing ozone.

### Example 7

### HfSiO₄ (Co-Flow) Deposition with O₃

A batch of 26 substrates is positioned on the susceptors of a boat within the mini-batch ALD chamber. The process chamber is maintained at a pressure of about 8 Torr at about 250° C. and exposed to a pretreatment gas containing ozone (15 at % ozone in oxygen) for about 40 minutes during a pretreatment process. Thereafter, a hafnium silicate layer is formed during an ALD process by sequentially exposing the substrates to a hafnium/silicon precursor mixture (TDEAH/Tris-DMAS (1:1) in nitrogen carrier gas) and ozone (15 at % ozone in oxygen). The substrates are heated to about 300° C. and exposed to a plurality of ALD cycles. Each ALD cycle includes flowing the TDEAH/Tris-DMAS mixture into the chamber for about 60 seconds, evacuating the chamber for about 30 seconds, flowing nitrogen into the chamber for about 30 seconds, evacuating the chamber for about 30 seconds, flowing ozone into the chamber for about 60 seconds, evacuating the chamber for about 30 seconds, flowing nitrogen into the chamber for about 30 seconds and evacuating the chamber for about 30 seconds. The ALD cycle is repeated a total of 8 times to form a hafnium silicate layer with a thickness of about 20 Å. Thereafter, the process chamber is maintained with a pressure of about 8 Torr at about 300° C. and exposed to a treatment gas containing nitrogen for about 5 minutes during an intermediate treatment process. Subsequently, 8 cycles of the ALD cycle and the intermediate treatment process are sequentially repeated as a deposition/treatment cycle. The deposition/treatment cycle is conducted 5 times to form a hafnium silicate layer with a thickness of about 100 Å. During a post-treatment process, the chamber is maintained with a pressure of about 8 Torr at about 250° C. for about 40 minutes and exposed to a post-treatment gas containing ozone.

### Example 8

### SiNₓ with Si₂Cl₆ and NH₃

A mini-batch ALD chamber is treated with a continuous flow of ammonia (NH₃) at a process temperature of about 550° C. The NH₃ has a flow rate of about 3.5 slm and the chamber is maintained at pressure of about 8 Torr for about 12.5 minutes. Thereafter, the chamber is evacuated for about 30 seconds. Subsequently, the chamber is treated with a simulated SiNₓ process with N₂ substituted for hexachlorodisilane (HCD) and with NH₃. The chamber is loaded with several bare Si wafers to monitor particle levels.

For the N₂/NH₃ process, the chamber is treated with the following process steps. The chamber is cycle purged 5 times with a duration of about 5 seconds per step with a N₂ flow of about 6.3 slm and an argon (Ar) flow of about 0.4 slm. With the pressure fixed at about 8 Torr, the chamber is continuously purged with a N₂ flow of about 6.3 slm and an Ar flow of about 0.4 slm for about 45 seconds. The chamber is evacuated with a N₂ flow of about 1.3 slm and an Ar flow of about 0.4 slm for about 15 seconds. The chamber is treated to 10 simulated ALD SiNₓ (N₂/NH₃) cycles. The chamber is cycle purged 20 times with an NH₃ flow of about 3.5 slm and a N₂ flow of about 0.75 slm. The purge step has duration about 15 seconds, and the pump step has duration about 20 seconds. The chamber is continuously purged with a N₂ flow of about 6.3 slm and an Ar flow of about 0.4 slm. Finally, the chamber is evacuated for 30 seconds with no gas flow.

For the simulated ALD SiNₓ process, the adders for size greater than 0.12 μm were 26 in PM slot 24 and were 57 in PM slot 8 in one experiment. The chamber is then treated with a 10 cycle SiNₓ process to fix any loose particles in the chamber. After this pre-treatment of the chamber, processing with product wafers may continue until particle levels are larger than specification or until the chamber is idle for more than 8 hours. While the chamber is idle, the chamber should be subjected to simulated ALD SiNₓ (N₂/N₂) process. Following chamber treatments, substrates were positioned on the susceptors of a boat within the mini-batch ALD chamber for ALD SiNₓ.

The wafers were treated in the following manner. The chamber is cycle purged 5 times with a duration of about 5 seconds per step with a N₂ flow of about 6.3 slm and an Ar flow of about 0.4 slm. With the pressure fixed at about 8 Torr, the chamber and substrates are continuously purged with a N₂ flow of about 6.3 slm and an Ar flow of about 0.4 slm for about 1,765 seconds. The chamber and wafers are evacuated with a N₂ flow of about 1.3 slm and an Ar flow of about 0.4 slm for about 15 seconds. The chamber and wafers are treated to an arbitrary number of ALD SiNₓ (HCD/NH₃) cycles. The chamber and wafers are cycle purged 20 times with an NH₃ flow of about 3.5 slm and a N₂ flow of about 0.75 slm. The purge step has duration about 15 seconds, and the pump step has duration about 20 seconds. The chamber and wafers are continuously purged with an N₂ flow of about 6.3 slm and an Ar flow of about 0.4 slm. Finally, the chamber and wafers are evacuated for about 30 seconds with no gas flow. With the chamber treatment and the chamber/wafer treatment, in-film particle adders for size greater than 0.2 μm are typically less than 50 for ALD SiNₓ film thickness of approximately 100 Å. Without the chamber treatment and the chamber/wafer treatment, in-film particle adders for size greater than 0.2 μm are typically greater than about 500 for ALD SiNₓ film thickness of approximately 100 Å.

### Example 9

### SiNₓ with Si₂Cl₆ and NH₃ (Hypothetical)

A mini-batch ALD chamber is treated with a continuous flow of NH₃ at a process temperature of about 550° C. The NH₃ has a flow rate of about 3.5 slm and the chamber is maintained at pressure of about 8 Torr for about 12.5 minutes. Thereafter, the chamber is evacuated for about 30 seconds. Subsequently, the chamber is treated with a SiNₓ process containing hexachlorodisilane (HCD) and NH₃. The chamber is loaded with several bare Si wafers to monitor particle levels.

For the NH₃ step of the process, the chamber is treated with the following process steps. The chamber is cycle purged 5 times with a duration of about 5 seconds per step with a HCD flow of about 6.3 slm and an Ar flow of about 0.4 slm. With the pressure fixed at about 8 Torr, the chamber is continuously purged with a HCD flow of about 6.3 slm and an Ar flow of about 0.4 slm for about 45 seconds. The chamber is evacuated with a HCD flow of about 1.3 slm and an Ar flow of about 0.4 slm for about 15 seconds. The chamber is treated to 10 ALD SiNₓ (HCD/NH₃) cycles. The chamber is cycle purged 20 times with an NH₃ flow of about 3.5 slm and a HCD flow of about 0.75 slm. The purge step has duration about 15 seconds, and the pump step has duration about 20 seconds. The chamber is continuously purged with a HCD flow of about 6.3 slm and an Ar flow of about 0.4 slm. Finally, the chamber is evacuated for 30 seconds with no gas flow.

For the ALD SiNₓ process, the adders for size greater than 0.12 μm were 26 in PM slot 24 and were 57 in PM slot 8 in one experiment. The chamber is then treated with a 10 cycle SiNₓ process to fix any loose particles in the chamber. After this pre-treatment of the chamber, processing with product wafers may continue until particle levels are larger than specification or until the chamber is idle for more than 8 hours. While the chamber is idle, the chamber should be subjected to an ALD SiNₓ process. Following chamber treatments, substrates were positioned on the susceptors of a boat within the mini-batch ALD chamber for ALD SiNₓ.

The wafers were treated in the following manner. The chamber is cycle purged 5 times with a duration of about 5 seconds per step with a HCD flow of about 6.3 slm and an Ar flow of about 0.4 slm. With the pressure fixed at about 8 Torr, the chamber and substrates are continuously purged with a HCD flow of about 6.3 slm and an Ar flow of about 0.4 slm for about 1,765 seconds. The chamber and wafers are evacuated with a HCD flow of about 1.3 slm and an Ar flow of about 0.4 slm for about 15 seconds. The chamber and wafers are treated to an arbitrary number of ALD SiNₓ (HCD/NH₃) cycles. The chamber and wafers are cycle purged 20 times with a HCD flow of about 3.5 slm and a N₂ flow of about 0.75 slm. The purge step has duration about 15 seconds, and the pump step has duration about 20 seconds. The chamber and wafers are continuously purged with an HCD flow of about 6.3 slm and an Ar flow of about 0.4 slm. Finally, the chamber and wafers are evacuated for about 30 seconds with no gas flow. With the chamber treatment and the chamber/wafer treatment, in-film particle adders for size greater than 0.2 μm are typically less than 50 for ALD SiNₓ film thickness of approximately 100 Å. Without the chamber treatment and the chamber/wafer treatment, in-film particle adders for size greater than 0.2 μm are typically greater than about 500 for ALD SiNₓ film thickness of approximately 100 Å.

While the foregoing is directed to embodiments of the invention, other and further embodiments of the invention may be devised without departing from the basic scope thereof, and the scope thereof is determined by the claims that follow.

1. A method for forming a material on a substrate within a process chamber, comprising:
exposing a process chamber to a pretreatment process;
exposing at least one substrate within the process chamber to an ALD process comprising:
exposing the at least one substrate sequentially to at least two chemical precursors during an ALD cycle;
repeating the ALD cycle for a predetermined number of cycles; and
conducting a treatment process after each predetermined number of cycles; and
exposing the process chamber to a post-treatment process.

2. The method of claim 1, wherein the process chamber is a batch process chamber.

3. The method of claim 2, wherein the at least one substrate is a plurality of substrates containing 25 substrates or more.

4. The method of claim 3, wherein the plurality of substrates contains about 50 substrates or more.

5. The method of claim 4, wherein the plurality of substrates contains about 100 substrates.

6. The method of claim 1, wherein the pretreatment process and the post-treatment process each comprises a treatment gas independently selected from the group consisting of an inert gas, an oxidizing gas, a nitriding gas, a reducing gas, plasmas thereof, derivatives thereof and combinations thereof.

7. The method of claim 6, wherein the pretreatment process and the post-treatment process each comprise a treatment gas independently selected from the group consisting of ozone, water, ammonia, nitrogen, argon, hydrogen, plasmas thereof, derivatives thereof and combinations thereof.

8. A method for forming a material on a substrate within a process chamber, comprising:
exposing a batch chamber to a pretreatment process;
exposing a plurality of substrates within the batch process chamber to an ALD process for forming a material on the substrates, wherein the ALD process comprises:
exposing the substrates sequentially to a first chemical precursor and a second chemical precursor during an ALD cycle; and
repeating the ALD cycle to form a layer of the material having a predetermined thickness;
conducting at least one treatment process during the ALD process; and
exposing the process chamber to a post-treatment process.

9. The method of claim 8, wherein the at least one treatment process is conducted after a predetermined number of ALD cycles.

10. The method of claim 9, wherein the at least one treatment process and the predetermined number of ALD cycles are repeated during a process cycle.

11. The method of claim 10, wherein the process cycle is repeated to form the material.

12. The method of claim 11, wherein the plurality of substrates contains about 25 substrates or more.

13. The method of claim 8, wherein the pretreatment process and the post-treatment process each comprise a treatment gas independently selected from the group consisting of ozone, water, ammonia, nitrogen, argon, hydrogen, plasmas thereof, derivatives thereof and combinations thereof.

14. A method for forming a material on a substrate within a process chamber, comprising:
exposing a process chamber to a pretreatment process;
exposing a plurality of substrates within the process chamber to a deposition process for forming a material on the substrates;
conducting at least one treatment process during the deposition process; and
exposing the process chamber to a post-treatment process.

15. The method of claim 14, wherein the process chamber is a batch process chamber for a vapor deposition process.

16. The method of claim 15, wherein the process chamber is an ALD process chamber and the vapor deposition process contains an ALD cycle.

17. The method of claim 16, wherein the at least one treatment process is conducted after a predetermined number of ALD cycles.

18. The method of claim 17, wherein the at least one treatment process and the predetermined number of ALD cycles are repeated during a process cycle.

19. The method of claim 18, wherein the process cycle is repeated to form the material.

20. The method of claim 19, wherein the plurality of substrates contains about 25 substrates or more.

21. The method of claim 14, wherein the pretreatment process and the post-treatment process each comprise a treatment gas independently selected from the group consisting of ozone, water, ammonia, nitrogen, argon, hydrogen, plasmas thereof, derivatives thereof and combinations thereof.

22. A method for forming a material on a substrate within a process chamber, comprising:
exposing a batch process chamber to a pretreatment process;
exposing a plurality of substrates within the batch process chamber to an ALD process for forming a hafnium-containing material on the substrates, wherein the ALD process comprises:
exposing the substrates sequentially to a hafnium precursor and an oxidizing gas during an ALD cycle; and
repeating the ALD cycle to form a hafnium-containing layer having a predetermined thickness; and
conducting at least one treatment process during the ALD process.

23. The method of claim 22, wherein the at least one treatment process is conducted after a predetermined number of ALD cycles.

24. The method of claim 23, wherein the at least one treatment process and the predetermined number of ALD cycles are repeated during a process cycle.

25. The method of claim 24, wherein the process cycle is repeated to form the material.

26. The method of claim 22, wherein the plurality of substrates contains about 25 substrates or more.

27. The method of claim 26, wherein the pretreatment process and a post-treatment process each comprise a treatment gas independently selected from the group consisting of ozone, water, ammonia, nitrogen, argon, hydrogen, plasmas thereof, derivatives thereof and combinations thereof.
